(19) United States
(12) Patent Application Publication
(10) Pub. No.: US 2024/0413530 A1
(43) Pub. Date: Dec. 12, 2024

(54) DOUBLE BACK DRILL VIA FOR LOW COST PCB mmWAVE PHASED ARRAY ANTENNAS

(71) Applicant: JABIL INC., St. Petersburg, FL (US)

(72) Inventors: Ian Jeffery Timmins, St. Petersburg, FL (US); Babak Zarrin Rafie, St. Petersburg, FL (US); Youssef Faltone, St. Petersburg, FL (US); John Finnell, St. Petersburg, FL (US)

(21) Appl. No.: 18/694,733

(22) PCT Filed: Sep. 16, 2022
(86) PCT No.: PCT/US2022/076544

§ 371 Date: Mar. 22, 2024

Related U.S. Application Data
(60) Provisional application No. 63/261,477, filed on Sep. 22, 2021.

(51) Int. Cl. H01Q 3/34; H01Q 9/04

(52) U.S. Cl. CPC H01Q 3/34; H01Q 9/0407

(57) ABSTRACT

A mmWave antenna that has particular application to be used in a 5G radio. The antenna includes a RGB structure having a plurality of layers. The RGB structure includes a first via hole formed into the layers through one side of the RGB structure and filled with a first via and a second via hole formed into the layers through an opposite side of the RGB structure and filled with a second via, where the first and second vias are electrically coupled by an interconnect. Prepreg buildup layers are formed on the one side of the PCB structure and prepreg buildup layers are formed on the opposite side of the PCB structure. A beamforming IC is formed on the prepreg buildup layers on the one side of the PCB structure and an antenna radiating element is formed on the prepreg buildup layers on the opposite side of the PCB structure.

### BACKGROUND

### Field

This disclosure relates generally to a millimeter wave (mmWave) antenna and, more particularly, to a mmWave phased array antenna including interconnected back-drilled vias.

### Discussion of the Related Art

Cellular telecommunications companies began deploying fifth generation (5G) radio technology standard for cellular networks in 2019. The 5G radio standard utilizes a higher frequency spectrum than previous generations of commercial communications technologies. MmW phased array antennas are being designed and developed for the 5G protocol that provides increased performance over 4G systems while also reducing costs. 5G mmWave antennas typically require precise manufacturing of printed circuit boards (PCBs) because antenna features on the order of a wavelength are at the limits of manufacturing tolerance of the PCB fabrication process.

One of the most challenging RF circuits for the development of a PCB based phased array antenna design is the transition structures, i.e., vias, between layers in the PCB. For example, the transition from the feed layer to the radiating elements, where these vias tend to be the largest vias on the PCB structure, is difficult to produce. Generally, these antenna designs include a high layer count PCB that tends toward using microvias as interconnect structures between the layers. This makes for a complex PCB fabrication process that is not suited to low cost high volume manufacturing. Furthermore, there have been PCB fabrication development methods to support fine pitch ball grid array (BGA) packages in application specific integrated circuit (ASIC) designs, where a conventional PCB is used, with plated through hole (PTH) vias, and then a number of subsequent prepreg layers using microvias are added to the PCB structure as a technique to provide trace routing to “break out” of the fine pitch BGA, which otherwise using PTH via technology would prove challenging, or even impossible as pin counts on the BGA ASIC increase.

### SUMMARY

The following discussion discloses and describes a mmWave phased array antenna that has particular application to be used in a 5G radio. The antenna includes a PCB structure having a plurality of layers. The PCB structure includes a first via hole formed into the layers through one side of the PCB structure and partially filled with a first via and a second via hole formed into the layers through an opposite side of the PCB structure and partially filled with a second via, where the first and second vias are electrically coupled by an interconnect. Prepreg buildup layers are formed on the one side of the PCB structure and prepreg buildup layers are formed on the opposite side of the PCB structure. At least one beamforming integrated circuit (IC) is formed on the prepreg buildup layers on the one side of the PCB structure and at least one antenna radiating element is formed on the prepreg buildup layers on the opposite side of the PCB structure.

Additional features of the disclosure will become apparent from the following description and appended claims, taken in conjunction with the accompanying drawings.

### BRIEF DESCRIPTION OF THE DRAWINGS

FIG. 1 is a profile view of a mmWave phased array antenna including interconnected back-drilled vias; and

FIG. 2 is a layout illustration of the mmWave antenna showing a beamforming IC, a patch antenna and the interconnected back-drilled vias.

### DETAILED DESCRIPTION

The following discussion of the embodiments of the disclosure directed to a mmWave phased array antenna including interconnected back-drilled vias is merely exemplary in nature, and is in no way intended to limit the disclosure or its applications or uses. For example, the discussion herein refers to the antenna as being part of a phased array antenna for a 5G radio. However, as will be appreciated by those skilled in the art, the antenna will have other applications.

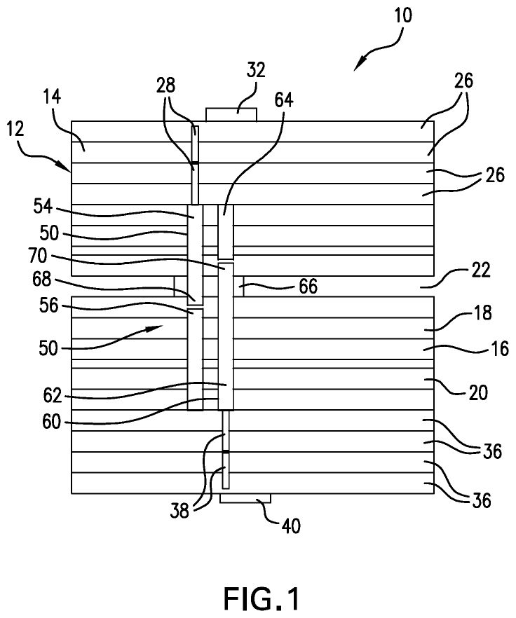

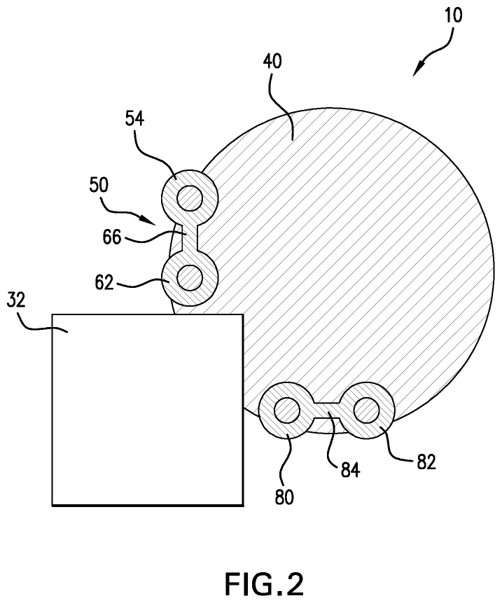

FIG. 1 is a profile view a mmWave phased array antenna 10 and FIG. 2 is a layout illustration of a portion of the mmWave antenna 10, where the antenna 10 can be part of a 5G radio. The antenna 10 includes a PCB structure 12 having a stack of layers 14 including core dielectric layers 16, dielectric insulating prepreg layers 18, copper layers 20 and a feed layer 22, where the number, thickness, configuration, material, etc. of the layers 14 would be designed for a particular antenna as would be well understood by those skilled in the art. Prepreg buildup layers 26 are formed on a top of the PCB structure 12 and stacked microvias 28 are formed through the layers 26, where the layers 26 and the microvias 28 support BGA breakup. A beamforming IC 32 is provided on top of the buildup layers 26 and includes the circuitry necessary for beam phase combining and beam steering for multiple radiating elements in the phased array antenna 10 in a manner well understood by those skilled in the art, where the vias 28 provide an electrical connection to the beamforming IC 32. Multiple beamforming ICs would be employed in the phased array antenna 10. Prepreg buildup layers 36 are formed on a bottom of the PCB structure 12 and stacked microvias 38 are formed through the layers 36, where the layers 36 and the microvias 38 support BGA breakup. A patch antenna radiating element 40 is formed on an outermost one of the layers 36 and would be one of many radiating elements formed on the PCB structure 12 to provide the phased array antenna 10, where the radiating element 40 could be formed of ½ oz copper, and where the vias 38 provide an electrical connection to the radiating element 40.

Prior to the layers 26 and 36 being formed on the PCB structure 12, a via structure 50 is formed in the PCB structure 12 to provide an electrical connection between the vias 28 and 38, and thus between the beamforming IC 32 and the radiating element 40. A hole 52 is drilled from the top side of the PCB structure 12 and a via 54 is formed in part of the hole 52 and the rest of the hole 52 is filled with a dielectric 56. A hole 60 is drilled from the bottom side of the PCB structure 12 and a via 62 is formed in part of the hole 60 and the rest of the hole 60 is filled with a dielectric 64, where the holes 52 and 60 are provided as close together as the manufacturing tolerances will allow. An interconnect 66 in the feed layer 22 electrically couples the vias 54 and 62. A stub 68 of the via 54 extends past the interconnect 66 adjacent to the dielectric 56 and a stub 70 of the via 62 extends past the interconnect 66 adjacent to the dielectric 64 and have a length for impedance matching purposes between the vias 54 and 62.

FIG. 2 shows an additional set of vias 80 and 82 connected by an interconnect 84 and orthogonal to the vias 54 and 62 to support another signal polarization.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. An antenna comprising:
a printed circuit board (PCB) structure including a plurality of layers, said PCB structure including a first via hole formed into the layers through one side of the PCB structure and partially filled with a first via and a second via hole formed into the layers through an opposite side of the PCB structure and partially filled with a second via, wherein the first and second vias are electrically coupled by an interconnect;
prepreg buildup layers formed on the one side of the PCB structure and prepreg buildup layers formed on the opposite side of the PCB structure;
at least one beamforming integrated circuit (IC) formed on the prepreg buildup layers on the one side of the PCB structure; and
at least one antenna radiating element formed on the prepreg buildup layers on the opposite side of the PCB structure.

2. The antenna according to claim 1 wherein the prepreg layers on the one side of the PCB structure include microvias electrically coupled to the beam forming IC and the first via and the prepreg layers on the opposite side of the PCB structure include microvias electrically coupled to the at least one antenna radiating element and the second via.

3. The antenna according to claim 1 wherein the first via includes a first stub that extends beyond the interconnect and the second via includes a second stub that extends beyond the interconnect.

4. The antenna according to claim 1 wherein the at least one antenna radiating element is a patch antenna radiating element.

5. The antenna according to claim 1 wherein the interconnect is in a feed layer in the PCB structure.

6. The antenna according to claim 1 wherein the antenna is a phased array antenna, the at least one beamforming IC is a plurality of beamforming ICs and the at least one antenna radiating element is a plurality of antenna radiating elements.

7. The antenna according to claim 6 wherein the antenna is part of a 5G radio.

8. A phased array antenna comprising:
a printed circuit board (PCB) structure including a plurality of layers, said PCB structure including a first via hole formed into the layers through one side of the PCB structure and partially filled with a first via and a second via hole formed into the layers through an opposite side of the PCB structure and partially filled with a second via, wherein the first and second vias are electrically coupled by an interconnect provided in a feed layer of the plurality of layers;
prepreg buildup layers formed on the one side of the PCB structure and prepreg buildup layers formed on the opposite side of the PCB structure;
at least one beamforming integrated circuit (IC) formed on the prepreg buildup layers on the one side of the PCB structure; and
at least one patch antenna radiating element formed on the prepreg buildup layers on the opposite side of the PCB structure.

9. The antenna according to claim 8 wherein the prepreg layers on the one side of the PCB structure include microvias electrically coupled to the beam forming IC and the first via and the prepreg layers on the opposite side of the PCB structure include microvias electrically coupled to the at least one antenna radiating element and the second via.

10. The antenna according to claim 8 wherein the first via includes a first stub that extends beyond the interconnect and the second via includes a second stub that extends beyond the interconnect.

11. The antenna according to claim 8 the antenna is part of a 5G radio.
